(19) United States
(12) Patent Application Publication
(10) Pub. No.: US 2024/0214026 A1
(43) Pub. Date: Jun. 27, 2024

(54) MAGNITUDE AND PHASE ADJUSTMENT METHOD FOR HIGH OUTPUT POWER RF POWER AMPLIFIER COMBINING

(71) Applicant: Telefonaktiebolaget LM Ericsson (publ), Stockholm (SE)

(72) Inventors: Yiming SHEN, Ottawa (CA); Carl CONRADI, Ottawa (CA); John ILOWSKI, Nepean (CA)

(21) Appl. No.: 18/557,094

(22) PCT Filed: Apr. 30, 2021
(86) PCT No.: PCT/IB2021/053630

§ 371 Date: Oct. 25, 2023

(51) Int. Cl. H04B 1/712; H03F 3/24; H03G 3/30; H04B 1/04

(52) U.S. Cl. CPC H04B 1/712; H03F 3/245; H03G 3/3042; H04B 1/0458; H04B 1/0483; H03F 2200/451

(57) ABSTRACT

A method and a transmitter providing magnitude and phase adjustment for high output power radio frequency (RF) power amplifier (PA) combining are provided. According to one aspect, a method includes making adjustments to the magnitude and phase of a received signal to produce first and second amplifier input signals. The method also includes amplifying a respective one of the first and second amplifier input signals via respective first and second power amplifiers. The method further includes combining outputs from each of the first and second power amplifiers to produce a first transmit signal, and to produce an isolation signal indicative of an amount by which the outputs from the first and second power amplifiers differ in magnitude and phase. The isolation signal is used to adjust the received signal to drive the isolation signal toward zero.

### TECHNICAL FIELD

This disclosure relates to wireless communication and in particular, to magnitude and phase adjustment for high output power radio frequency (RF) power amplifier (PA) combining.

### BACKGROUND

The Third Generation Partnership Project (3GPP) has developed and is developing standards for Fourth Generation (4G) (also referred to as Long Term Evolution (LTE)) and Fifth Generation (5G) (also referred to as New Radio (NR)) wireless communication systems. Such systems provide, among other features, broadband communication between network nodes, such as base stations, and mobile wireless devices (WD), as well as communication between network nodes and between WDs. Sixth Generation (6G) wireless communication systems are also under development.

In a remote radio head (RRH) of a base station such as a gNB or eNB, high transmitter output power is desired due to ever-increasing demand for wireless communications. Transmitter output requirements may be between 100 Watts (W) to 160 W.

Various approaches have been taken to increase transmitter output power. In one approach, two power amplifiers (PAs) are combined using a power combiner or a hybrid coupler to produce one higher transmitter output power. However, such a solution require two transmitter amplifiers that are highly matched in gain and phase over frequency, time and temperature. Any mismatch in gain or phase causes huge reduction in output power and efficiency. To reduce the mismatch between the two amplifiers, care must be taken to choose matching power transistors, which increases the overall costs of the remote radio head (RRH). Even with careful matching, there is a high risk of degradation of performance and reliability over time when the RRH is deployed in the field.

In another approach, a three-way Doherty amplifier that provides different amplifiers for different peak to average power ratio (PAPRs) may be employed. But such design must start from scratch. Also, commercially available transistors are designed to be used in 80 W remote radio heads.

In summary, time and costs are involved to design power amplifiers (PAs) with the high power desired for present and future applications of RRHs.

### SUMMARY

Some embodiments advantageously provide a method and system for magnitude and phase adjustment for high output power radio frequency (RF) power amplifier combining.

According to one aspect, a method is provided for solving the problem of power amplifier mismatch over time, frequency and temperature. According to another aspect, a method is provided for field calibration of combined power amplifiers. Using some methods disclosed herein, the time to design a combined-amplifier power transmitter is reduced.

In some embodiments, a method utilizes the preexisting smaller output power PA to reduce hardware development time significantly for high output power RRHs. Currently, commercially available PA transistors are designed to be used in a RRH with 80w or lower output power. In order to have a 100w or higher PA, the PA circuit may be redesigned. Some embodiments combine two smaller and existing PA without requiring binning of transistors to achieve matching. Therefore, the product developing time is short.

In some embodiments, a method also provides cost saving for high output power RRHs. The calibration for the phase and gain setting is performed using an isolation port of a hybrid combiner or feedback from a Wilkinson power combiner. No new components are needed. Embodiments disclosed herein provide for calibration in production and in the field and also do not require binning of PA transistors.

According to one aspect, a transmitter configured to transmit radio frequency (RF) signals. The transmitter includes an adjustment circuit configured to make first adjustments to a magnitude and phase of a received signal to produce a first amplifier input signal and to make second adjustments to the magnitude and phase of the received signal to produce a second amplifier input signal. The transmitter also includes first and second power amplifiers in communication with the adjustment circuit, the first and second power amplifiers configured to amplify a respective one of the first and second amplifier input signals. The transmitter further includes a combiner in communication with the first and second power amplifiers, the combiner configured to combine outputs from each of the first and second power amplifiers to produce a first transmit signal, the combiner further configured to produce an isolation signal, the isolation signal being based at least in part on an amount by which the outputs from the first and second power amplifiers differ in magnitude and phase, the isolation signal being used to determine the first and second adjustments to the magnitude and phase of the received signal to drive the isolation signal toward zero.

According to this aspect, in some embodiments, the combiner is one of a hybrid coupler and a Wilkinson combiner. In some embodiments, the adjustment circuit is a digital circuit and the first and second adjustments to the magnitude and phase of the received signal are performed in a digital domain. In some embodiments, the adjustment circuit is an analog circuitry and the first and second adjustments to the magnitude and phase of the received signal are performed in an analog domain. In some embodiments, the transmitter further includes a memory in communication with the adjustment circuit to store the first and second adjustments to the magnitude and phase of the received signal. In some embodiments, the adjustment circuit includes a baseband signal processor configured to perform the magnitude and phase adjustments at baseband based at least in part on the isolation signal. In some embodiments, the adjustment circuit includes a first phase shifter and a first variable gain amplifier, VGA, in a first path to implement first magnitude and phase adjustments, and a second phase shifter and a second VGA in a second path to implement second magnitude and phase adjustments. In some embodiments, a baseband signal processor configured to control each phase shifter and each VGA based at least in part on the isolation signal. In some embodiments, the transmitter further includes a power splitter configured to receive an output signal from the baseband signal processor and split the received output signal into a first input signal and a second input signal upon which the first and second adjustments are made, respectively. In some embodiments, the power splitter further comprises digital circuitry configured to split the received output signal in a digital domain.

According to another aspect, a method in a transmitter configured to transmit radio frequency (RF) signals. The method includes making first adjustments to a magnitude and phase of a received signal to produce a first amplifier input signal and making second adjustments to the magnitude and phase of the received signal to produce a second amplifier input signal. The method also includes amplifying a respective one of the first and second amplifier input signals via respective first and second power amplifiers. The method also includes combining outputs from each of the first and second power amplifiers to produce a first transmit signal, and to produce an isolation signal, the isolation signal being based at least in part on an amount by which the outputs from the first and second power amplifiers differ in magnitude and phase, the isolation signal being used to determine the first and second adjustments to the magnitude and phase of the received signal to drive the isolation signal toward zero.

According to this aspect, in some embodiments, the combining is performed by one of a hybrid coupler and a Wilkinson combiner. In some embodiments, the first and second adjustments to the magnitude and phase of the received signal are performed in a digital domain. In some embodiments, the first and second adjustments to the magnitude and phase of the received signal are performed in an analog domain. In some embodiments, the method also includes storing the first and second adjustments to the magnitude and phase of the received signal. In some embodiments, the received signal is a baseband signal and the first and second adjustments are performed at baseband based at least in part on the isolation signal. In some embodiments, the first adjustments are implemented by a first phase shifter and a first variable gain amplifier, VGA, in a first path, and the second adjustments are implemented by a second phase shifter and a second VGA in a second path. In some embodiments, the method also includes providing a control signal to each phase shifter and each VGA, the control signal being based at least in part on the isolation signal. In some embodiments, the method also includes splitting the received signal into a first input signal input to the first path and a second input signal input to the second path. In some embodiments, the splitting is implemented in a digital domain.

### BRIEF DESCRIPTION OF THE DRAWINGS

A more complete understanding of the present embodiments, and the attendant advantages and features thereof, will be more readily understood by reference to the following detailed description when considered in conjunction with the accompanying drawings wherein:

FIG. 1 is a first example embodiment of a transmitter constructed in accordance with principles set forth herein using a hybrid coupler;

FIG. 2 is a second example embodiment of a transmitter constructed in accordance with principles set forth herein using a hybrid coupler;

FIG. 3 is a third example embodiment of a transmitter constructed in accordance with principles set forth herein using a hybrid coupler;

FIG. 4 is a first example embodiment of a transmitter constructed in accordance with principles set forth herein using a Wilkinson power combiner;

FIG. 5 is a second example embodiment of a transmitter constructed in accordance with principles set forth herein using a Wilkinson power combiner;

FIG. 6 is a second example embodiment of a transmitter constructed in accordance with principles set forth herein using a Wilkinson power combiner;

FIG. 7 is block diagram of one embodiment of a baseband signal processor constructed in accordance with principles disclosed herein; and

FIG. 8 is a flowchart of an example process in a remote radio head according to principles disclosed herein.

### DETAILED DESCRIPTION

Before describing in detail exemplary embodiments, it is noted that the embodiments reside primarily in combinations of apparatus components and processing steps related to magnitude and phase adjustment for high output power radio frequency (RF) power amplifier (PA) combining. Accordingly, components have been represented where appropriate by conventional symbols in the drawings, showing only those specific details that are pertinent to understanding the embodiments so as not to obscure the disclosure with details that will be readily apparent to those of ordinary skill in the art having the benefit of the description herein.

As used herein, relational terms, such as “first” and “second,” “top” and “bottom,” and the like, may be used solely to distinguish one entity or element from another entity or element without necessarily requiring or implying any physical or logical relationship or order between such entities or elements.

In some embodiments, methods for magnitude and phase adjustment for high output power radio frequency (RF) power amplifier combining are provided.

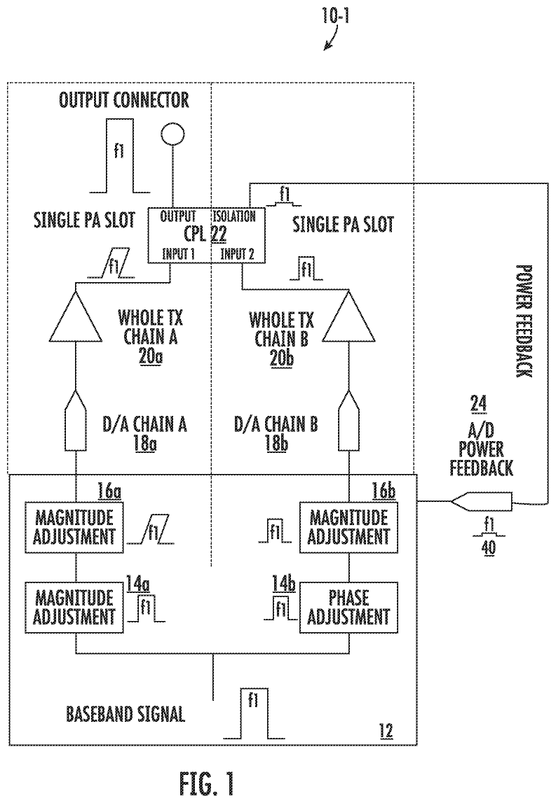

Referring now to the drawing figures, in which like reference numerals refer to like elements, there is shown in FIG. 1 a first example of a transmitter 10-1 of an RRH that performs power splitting and magnitude and phase adjustments in the digital domain at base band followed by amplification in the analog domain. In FIG. 1, a baseband signal is received by a baseband signal processor 12 and split into two branches. Each branch has respective phase adjustment circuits 14a, 14b, hereinafter referred to collectively as phase adjustment circuits 14. Each phase adjustment circuit 14 adjusts the phase of the signal in the respective branch. The output of the phase adjustment circuits 14a, 14b are input to respective magnitude adjustment circuits 16a, 16b, hereinafter referred to collectively as magnitude adjustment circuits 16. Each magnitude adjustment circuit 16 adjusts the magnitude of the signal in the respective branch. Phase adjustment circuits 14 and magnitude adjustment circuits 16 may be referred to collectively as adjustment circuits 14, 16.

The magnitude and phase adjusted signals in the two branches are converted to the analog domain by digital to analog (D/A) chains 18a and 18b, hereinafter referred to collectively as D/A converters 18. The output of each D/A converter 18a and 18b is input to a respective transmit chain 20a, 20b, hereinafter referred to as transmit chains 20. Each transmit chain 20a, 20b has a power amplifier.

The outputs of the transmit chains 20a and 20b are input to respective input ports of a hybrid coupler 22. The hybrid coupler 22 is a balanced device having an output port and an isolation port. If the two signals received on the input ports of the hybrid coupler 22 are equal in magnitude and phase, the signal power at the isolation port will be nearly zero and the signal power at the output port will be nearly the sum of the input signal powers at the respective input ports. To the extent that the two signals on the input ports of the hybrid coupler 22 are not equal in magnitude and phase, the power of the signal at the output port of the hybrid coupler 22 decreases and the power of the signal at the isolation port increases.

The signal from the isolation port of the hybrid coupler 22 is fed back to the baseband signal processor 12 via an analog to digital converter 24. The baseband signal processor 12 determines if a previous magnitude and phase adjustment resulted in a decrease or increase in the power feedback signal from the isolation port of the hybrid coupler. Based on this determination, the baseband processing signal processor 12 determines a next magnitude and phase adjustment predicted to drive the power feedback signal toward zero.

During factory calibration, the magnitude and phase of the signals input to each transmitter chain 20 may be adjusted to drive the power feedback signal from the isolation port of the hybrid coupler 22 toward zero. Once the minimal power is found during calibration, the corresponding magnitude and phase settings of the phase adjustment circuitry 14 and the magnitude adjustment circuitry 16 are stored in a memory of the RRH.

When the RRH has been deployed in the field, the power feedback signal from the isolation port of the hybrid coupler 22 may be monitored constantly or periodically, for example. When the power fed back from the isolation port of the hybrid coupler 22 is larger than a threshold, the magnitude and phase may be adjusted automatically to find a setting of the magnitude and phase of each branch that minimizes the power feedback signal from the isolation port of the hybrid coupler 22.

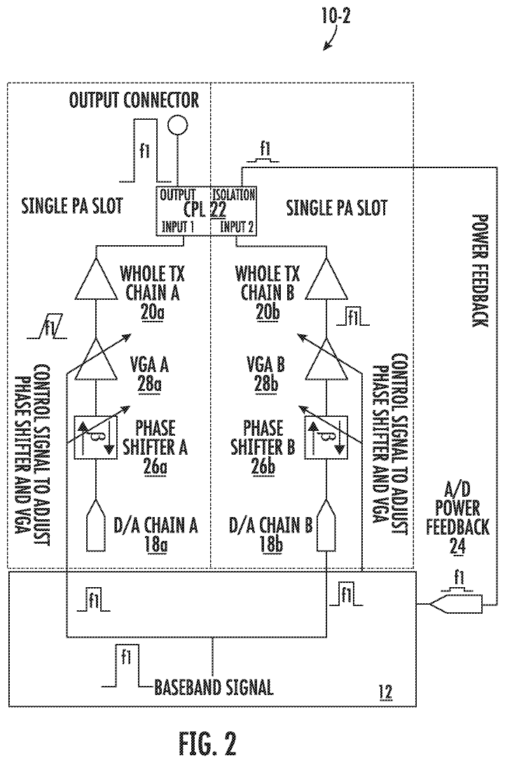

FIG. 2 is a block diagram of a second example of a transmitter 10-2 having digital power splitting, analog magnitude and phase adjustments and combining with a hybrid combiner. In FIG. 2, a baseband signal is split into two branches in the digital baseband signal processor 12. The signals in each branch are converted to the analog domain by D/A converters 18 and input to respective analog phase shifters 26a and 26b, hereinafter referred to collectively as analog phase shifters 26. An amount of phase introduced by the analog phase shifters 26 is adjustable by phase control signals from the baseband signal processor 12. The phase control signals from the baseband signal processor 12 are based at least in part on a power feedback signal from the isolation port of the hybrid coupler 22 via the A/D converter 24. The outputs of the analog phase shifters 26 are input to respective variable gain amplifiers (VGAs) 28a and 28b, hereinafter referred to collectively as VGAs 28. An amount of gain or attenuation provided by the VGAs 28 is adjustable by magnitude control signals from the baseband signal processor 12. The magnitude control signals from the baseband signal processor 12 are based at least in part on a power feedback signal from the isolation port of the hybrid coupler 22 via the A/D converter 24.

The analog phase shifters 26 and VGAs 28 may be adjusted during calibration at the factory or in the field to minimize power from the isolation port of the hybrid coupler 22. Thus, the analog phase shifters 26 and VGAs 28 may be referred collectively as adjustment circuits 26, 28.

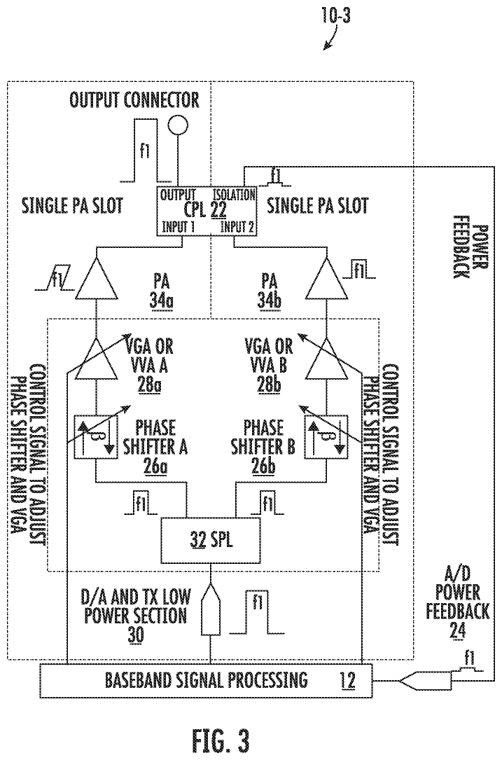

FIG. 3 is a block diagram of a third example of a transmitter 10-3 that performs analog phase shifting, analog magnitude and phase adjustments and combining using a hybrid coupler. The baseband signal processor 12 receives and processes a signal to be transmitted by performing such baseband functions as modulation and coding, for example. The baseband signal processor 12 processes the signal in the digital domain. The processed baseband signal is input to a D/A converter and low power section 30 which converts the digital baseband signal from the baseband signal processor 12 to an analog signal, and amplifies the analog signal. The amplified analog signal is split into two branches by a splitter 32.

The signals in each branch are input to respective analog phase shifters 26a and 26b, hereinafter referred to collectively as analog phase shifters 26. An amount of phase introduced by the analog phase shifters 26 is adjustable by phase control signals from the baseband signal processor 12. The phase control signals from the baseband signal processor 12 are based at least in part on a power feedback signal from the isolation port of the hybrid coupler 22 via the A/D converter 24. The outputs of the analog phase shifters 26 are input to respective variable gain amplifiers (VGAs) 28a and 28b. An amount of gain or attenuation provided by the VGAs 28 is adjustable by magnitude control signals from the baseband signal processor 12. The magnitude control signals from the baseband signal processor 12 are based at least in part on a power feedback signal from the isolation port of the hybrid coupler 22 via the A/D converter 24. The magnitude and phase in each branch will be adjusted to minimize power from the isolation port of the hybrid coupler 22. Also, the VGA and phase shifter settings can be adjusted in the field once the RRH has been deployed. The outputs of the VGAs 28 are input to respective power amplifiers 34a and 34b which amplify the signals and input them to the input ports 1 and 2 of the hybrid coupler 22.

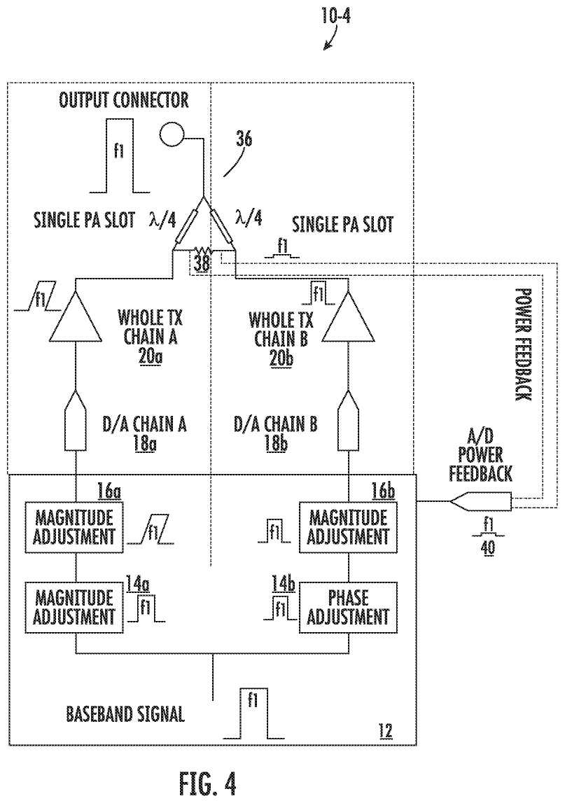

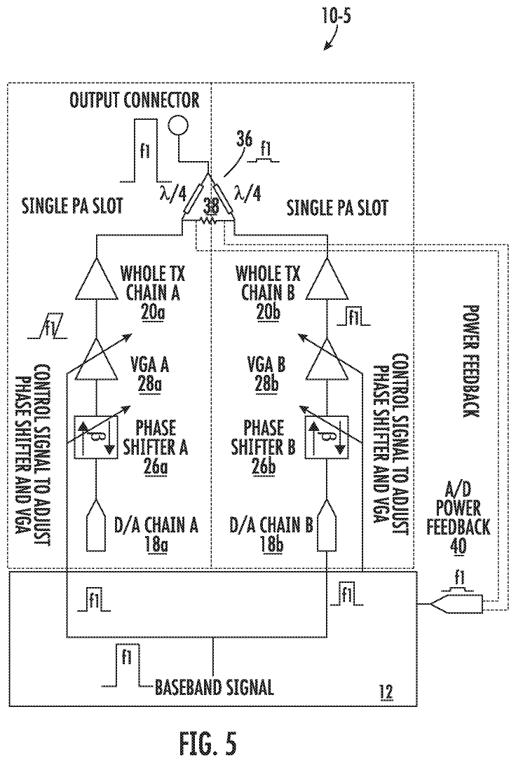

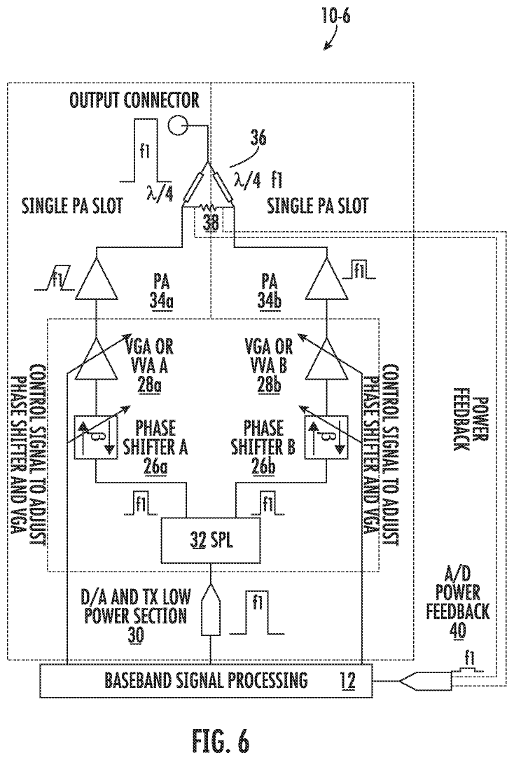

FIGS. 4, 5 and 6 are similar to FIGS. 1, 2 and 3, respectively, except that the hybrid coupler 22 is replaced by a Wilkinson power combiner 36 which combines power from the two branches. The differential voltage across the resistor 38 in the Wilkinson power combiner 36 will be nearly zero when the magnitude and phase of the two branches are well-matched. To the extent that the two signals on the input ports of the Wilkinson power combiner 36 are not equal in magnitude and phase, the power of the signal at the output port of the Wilkinson power combiner 36 decreases and the power of the differential signal across the resistor 38 of the Wilkinson power combiner 36 increases. The differential signal across the resistor 38 of the Wilkinson power combiner 36 is fed back to the baseband signal processor 12 via an analog to digital converter 40 to be used to determine magnitude and phase adjustments for the signals in the two branches. Thus, the differential signal across the resistor 38 is used as a power feedback signal. Note that the term combiner, as used herein, may refer to any power combiner that provides a differential signal having power that depends on mismatch between the amplifiers 34. For example, the hybrid coupler 22 and the Wilkinson power combiner 36 are examples of combiners.

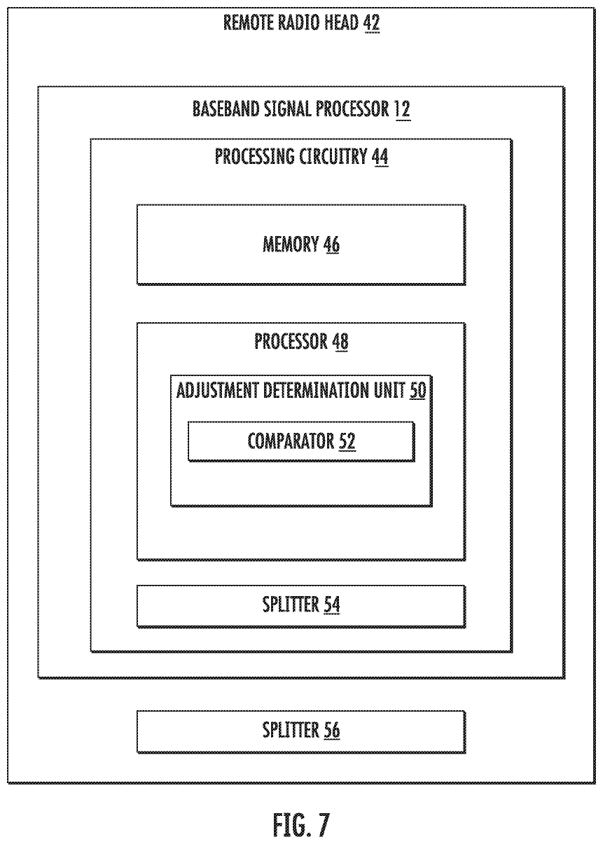

FIG. 7 is a block diagram of remote radio head 42 having a baseband signal processor 12. Remote radio head 42 may include transmitter 10. The baseband signal processor 12 has processing circuitry 44 which includes a memory 46 and a processor 48. In particular, in addition to or instead of a processor, such as a central processing unit, and memory, the processing circuitry 44 may comprise integrated circuitry for processing and/or control, e.g., one or more processors and/or processor cores and/or FPGAs (Field Programmable Gate Array) and/or ASICs (Application Specific Integrated Circuitry) adapted to execute instructions. The processor 48 may be configured to access (e.g., write to and/or read from) the memory 46, which may comprise any kind of volatile and/or nonvolatile memory, e.g., cache and/or buffer memory and/or RAM (Random Access Memory) and/or ROM (Read-Only Memory) and/or optical memory and/or EPROM (Erasable Programmable Read-Only Memory).

The processor 48 may be configured to implement an adjustment determination unit 50. A purpose of the adjustment determination unit is to determine an adjustment to magnitude and phase to drive the power feedback signal from the isolator port of the hybrid coupler 22 toward zero or to drive the power feedback signal from the Wilkinson power combiner 36 toward zero. In some embodiments, an algorithm may be implemented to drive the power feedback signal toward zero. Such algorithm may include comparing by comparator 52 a present power feedback signal value to a previous power feedback signal value to determine if the previous magnitude and phase adjustments resulted in a lower power feedback signal value. If the previous magnitude and phase adjustment resulted in a lower feedback signal value, a next magnitude and phase adjustment is determined that is likely to further drive the power feedback signal toward zero. Algorithms for finding the magnitude and phase adjustment that drives the power feedback signal toward zero may be adapted from known minimization algorithms. The comparator 52 may also compare a present power feedback signal value to a threshold to determine if a magnitude and phase adjustment should be changed. As noted above with reference to FIGS. 1 and 4, the power splitter 54 may be implemented in the digital domain in the baseband signal processor 12. Alternatively, the power splitter 56 may be implemented in the analog domain.

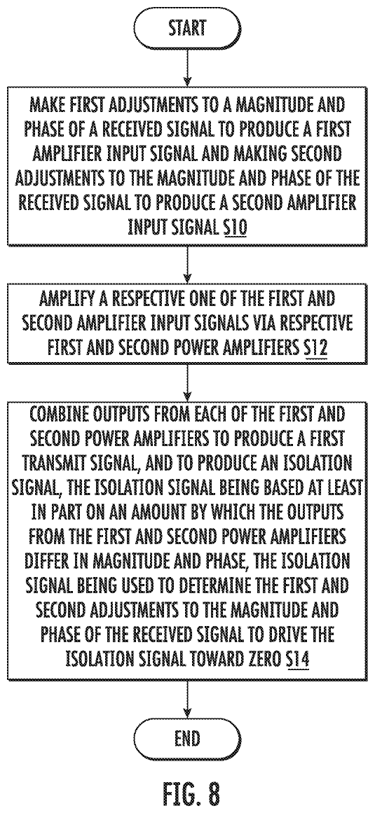

FIG. 8 is a flowchart of one example process in a remote radio head 42 that may be implemented at least in part by the baseband signal processor 12, transmit chains 20 (which may include PAs 34a and 34b), hybrid coupler 22 or Wilkinson power combiner 36 and A/D converter 24 or 40, and D/A converters 18 and 30. The process includes making first adjustments to a magnitude and phase of a received signal to produce a first amplifier input signal and making second adjustments to the magnitude and phase of the received signal to produce a second amplifier input signal. (Block S10). The process further includes amplifying a respective one of the first and second amplifier input signals via respective first and second power amplifiers (Block S12). The process further includes combining outputs from each of the first and second power amplifiers to produce a first transmit signal, and to produce an isolation signal, the isolation signal being based at least in part on an amount by which the outputs from the first and second power amplifiers differ in magnitude and phase, the isolation signal being used to determine the first and second adjustments to the magnitude and phase of the received signal to drive the isolation signal toward zero (Block S14).

Thus, some features of some embodiments may include:
Combining two transmit branches for higher power;
Splitting RF signals for the two different transmit branches in the digital or analog domain;
Magnitude and phase settings for the two different transmit branches in the digital or analog domain;
The isolation port of the hybrid combiner used as a feedback signal for calibration of magnitude and phase settings; and/or
Calibration of magnitude and phase settings for the transmit branches performable in the factory or in the field.

According to one aspect, a transmitter 10 configured to transmit radio frequency (RF) signals. The transmitter 10 includes an adjustment circuit 14, 16, 26, 28 configured to make first adjustments to a magnitude and phase of a received signal to produce a first amplifier input signal and to make second adjustments to the magnitude and phase of the received signal to produce a second amplifier input signal. The transmitter 10 also includes first and second power amplifiers 34a, 34b in communication with the adjustment circuit 14, 16, 26, 28, the first and second power amplifiers 34a, 34b configured to amplify a respective one of the first and second amplifier input signals. The transmitter 10 further includes a combiner 22, 36 in communication with the first and second power amplifiers 34a, 34b, the combiner 22, 36 configured to combine outputs from each of the first and second power amplifiers 34a, 34b to produce a first transmit signal, the combiner 22, 36 further configured to produce an isolation signal, the isolation signal being based at least in part on an amount by which the outputs from the first and second power amplifiers 34a. 34b differ in magnitude and phase, the isolation signal being used to determine the first and second adjustments to the magnitude and phase of the received signal to drive the isolation signal toward zero.

According to this aspect, in some embodiments, the combiner is one of a hybrid coupler 22 and a Wilkinson combiner 36. In some embodiments, the adjustment circuit 14, 16 is a digital circuit and the first and second adjustments to the magnitude and phase of the received signal are performed in a digital domain. In some embodiments, the adjustment circuit 26, 28 is an analog circuit and the first and second adjustments to the magnitude and phase of the received signal are performed in an analog domain. In some embodiments, the transmitter 10 further includes a memory 46 in communication with the adjustment circuit 14, 16, 26, 28 to store the first and second adjustments to the magnitude and phase of the received signal. In some embodiments, the adjustment circuit 14, 16 includes a baseband signal processor 12 configured to perform the magnitude and phase adjustments at baseband based at least in part on the isolation signal. In some embodiments, the adjustment circuit 26, 28 includes a first phase shifter 26a and a first variable gain amplifier, VGA, 28a in a first path to implement first magnitude and phase adjustments, and a second phase shifter 26b and a second VGA 28b in a second path to implement second magnitude and phase adjustments. In some embodiments, a baseband signal processor 12 configured to control each phase shifter 26 and each VGA 28 based at least in part on the isolation signal. In some embodiments, the transmitter 10 further includes a power splitter 54, 56 configured to receive an output signal from the baseband signal processor 12 and split the received output signal into a first input signal and a second input signal upon which the first and second adjustments are made, respectively. In some embodiments, the power splitter 54 further comprises digital circuitry configured to split the received output signal in a digital domain.

According to another aspect, a method in a transmitter 10 configured to transmit radio frequency (RF) signals. The method includes making first adjustments, via the adjustment determiner unit 50, to a magnitude and phase of a received signal to produce a first amplifier input signal and making second adjustments to the magnitude and phase of the received signal to produce a second amplifier input signal. The method also includes amplifying, via a power amplifier 34 a respective one of the first and second amplifier input signals via respective first and second power amplifiers 34a, 34b. The method also includes combining, via a hybrid coupler 22 or Wilkinson power combiner 36, outputs from each of the first and second power amplifiers 34 to produce a first transmit signal, and to produce an isolation signal, the isolation signal being based at least in part on an amount by which the outputs from the first and second power amplifiers 34 differ in magnitude and phase, the isolation signal being used to determine the first and second adjustments to the magnitude and phase of the received signal to drive the isolation signal toward zero.

According to this aspect, in some embodiments, the combining is performed by one of a hybrid coupler 22 and a Wilkinson power combiner 36. In some embodiments, the first and second adjustments to the magnitude and phase of the received signal are performed in a digital domain. In some embodiments, the first and second adjustments to the magnitude and phase of the received signal are performed in an analog domain. In some embodiments, the method also includes storing the first and second adjustments to the magnitude and phase of the received signal. In some embodiments, the received signal is a baseband signal and the first and second adjustments are performed at baseband based at least in part on the isolation signal. In some embodiments, the first adjustments are implemented by a first phase shifter 26a and a first variable gain amplifier, VGA, 28a in a first path, and the second adjustments are implemented by a second phase shifter 26b and a second VGA in a second path 28b. In some embodiments, the method also includes providing a control signal to each phase shifter 26 and each VGA 28, the control signal being based at least in part on the isolation signal. In some embodiments, the method also includes splitting, via a splitter 54, 56, the received signal into a first input signal input to the first path and a second input signal input to the second path. In some embodiments, the splitting is implemented in a digital domain by the splitter 54.

As will be appreciated by one of skill in the art, the concepts described herein may be embodied as a method, data processing system, and/or computer program product. Accordingly, the concepts described herein may take the form of an entirely hardware embodiment, an entirely software embodiment or an embodiment combining software and hardware aspects all generally referred to herein as a “circuit” or “module.” Furthermore, the disclosure may take the form of a computer program product on a tangible computer usable storage medium having computer program code embodied in the medium that can be executed by a computer. Any suitable tangible computer readable medium may be utilized including hard disks, CD-ROMs, electronic storage devices, optical storage devices, or magnetic storage devices.

Some embodiments are described herein with reference to flowchart illustrations and/or block diagrams of methods, systems and computer program products. It will be understood that each block of the flowchart illustrations and/or block diagrams, and combinations of blocks in the flowchart illustrations and/or block diagrams, can be implemented by computer program instructions. These computer program instructions may be provided to a processor of a general purpose computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks.

These computer program instructions may also be stored in a computer readable memory or storage medium that can direct a computer or other programmable data processing apparatus to function in a particular manner, such that the instructions stored in the computer readable memory produce an article of manufacture including instruction means which implement the function/act specified in the flowchart and/or block diagram block or blocks.

The computer program instructions may also be loaded onto a computer or other programmable data processing apparatus to cause a series of operational steps to be performed on the computer or other programmable apparatus to produce a computer implemented process such that the instructions which execute on the computer or other programmable apparatus provide steps for implementing the functions/acts specified in the flowchart and/or block diagram block or blocks. It is to be understood that the functions/acts noted in the blocks may occur out of the order noted in the operational illustrations. For example, two blocks shown in succession may in fact be executed substantially concurrently or the blocks may sometimes be executed in the reverse order, depending upon the functionality/acts involved. Although some of the diagrams include arrows on communication paths to show a primary direction of communication, it is to be understood that communication may occur in the opposite direction to the depicted arrows.

Computer program code for carrying out operations of the concepts described herein may be written in an object oriented programming language such as Java® or C++. However, the computer program code for carrying out operations of the disclosure may also be written in conventional procedural programming languages, such as the “C” programming language. The program code may execute entirely on the user's computer, partly on the user's computer, as a stand-alone software package, partly on the user's computer and partly on a remote computer or entirely on the remote computer. In the latter scenario, the remote computer may be connected to the user's computer through a local area network (LAN) or a wide area network (WAN), or the connection may be made to an external computer (for example, through the Internet using an Internet Service Provider).

Many different embodiments have been disclosed herein, in connection with the above description and the drawings. It will be understood that it would be unduly repetitious and obfuscating to literally describe and illustrate every combination and subcombination of these embodiments. Accordingly, all embodiments can be combined in any way and/or combination, and the present specification, including the drawings, shall be construed to constitute a complete written description of all combinations and subcombinations of the embodiments described herein, and of the manner and process of making and using them, and shall support claims to any such combination or subcombination.

It will be appreciated by persons skilled in the art that the embodiments described herein are not limited to what has been particularly shown and described herein above. In addition, unless mention was made above to the contrary, it should be noted that all of the accompanying drawings are not to scale. A variety of modifications and variations are possible in light of the above teachings without departing from the scope of the following claims.

1. A transmitter, configured to transmit radio frequency, RF, signals, the transmitter comprising:
an adjustment circuit configured to make first adjustments to a magnitude and phase of a received signal to produce a first amplifier input signal and to make second adjustments to the magnitude and phase of the received signal to produce a second amplifier input signal;
first and second power amplifiers in communication with the adjustment circuit, the first and second power amplifiers configured to amplify a respective one of the first and second amplifier input signals; and
a combiner in communication with the first and second power amplifiers, the combiner configured to combine outputs from each of the first and second power amplifiers to produce a first transmit signal, the combiner further configured to produce an isolation signal, the isolation signal being based at least in part on an amount by which the outputs from the first and second power amplifiers differ in magnitude and phase, the isolation signal being used to determine the first and second adjustments to the magnitude and phase of the received signal to drive the isolation signal toward zero.

2. The transmitter of claim 1, wherein the combiner is one of a hybrid coupler and a Wilkinson combiner.

3. The transmitter of claim 1, wherein the adjustment circuit is a digital circuit and the first and second adjustments to the magnitude and phase of the received signal are performed in a digital domain.

4. The transmitter of claim 1, wherein the adjustment circuit is an analog circuitry and the first and second adjustments to the magnitude and phase of the received signal are performed in an analog domain.

5. The transmitter of claim 1, further comprising a memory in communication with the adjustment circuit to store the first and second adjustments to the magnitude and phase of the received signal.

6. The transmitter of claim 1, wherein the adjustment circuit includes a baseband signal processor configured to perform the magnitude and phase adjustments at baseband based at least in part on the isolation signal.

7. The transmitter of claim 1, wherein the adjustment circuit includes a first phase shifter and a first variable gain amplifier, VGA, in a first path to implement first magnitude and phase adjustments, and a second phase shifter and a second VGA in a second path to implement second magnitude and phase adjustments.

8. The transmitter of claim 7, further comprising a baseband signal processor configured to control each phase shifter and each VGA based at least in part on the isolation signal.

9. The transmitter of claim 8, further comprising a power splitter configured to receive an output signal from the baseband signal processor and split the received output signal into a first input signal and a second input signal upon which the first and second adjustments are made, respectively.

10. The transmitter of claim 9, wherein the power splitter further comprises digital circuitry configured to split the received output signal in a digital domain.

11. A method in a transmitter, configured to transmit radio frequency, RF, signals, the method comprising:
making first adjustments to a magnitude and phase of a received signal to produce a first amplifier input signal and making second adjustments to the magnitude and phase of the received signal to produce a second amplifier input signal;
amplifying a respective one of the first and second amplifier input signals via respective first and second power amplifiers; and
combining outputs from each of the first and second power amplifiers to produce a first transmit signal, and to produce an isolation signal, the isolation signal being based at least in part on an amount by which the outputs from the first and second power amplifiers differ in magnitude and phase, the isolation signal being used to determine the first and second adjustments to the magnitude and phase of the received signal to drive the isolation signal toward zero.

12. The method of claim 11, wherein the combining is performed by one of a hybrid coupler and a Wilkinson combiner.

13. The method of claim 11, wherein the first and second adjustments to the magnitude and phase of the received signal are performed in a digital domain.

14. The method of claim 11, wherein the first and second adjustments to the magnitude and phase of the received signal are performed in an analog domain.

15. The method of claim 11, wherein further comprising storing the first and second adjustments to the magnitude and phase of the received signal.

16. The method of claim 11, wherein the received signal is a baseband signal and the first and second adjustments are performed at baseband based at least in part on the isolation signal.

17. The method of claim 11, wherein the first adjustments are implemented by a first phase shifter and a first variable gain amplifier, VGA, in a first path, and the second adjustments are implemented by a second phase shifter and a second VGA in a second path.

18. The method of claim 17, further comprising providing a control signal to each phase shifter and each VGA, the control signal being based at least in part on the isolation signal.

19. The method of claim 18, further comprising splitting the received signal into a first input signal input to the first path and a second input signal input to the second path.

20. The method of claim 19, wherein the splitting is implemented in a digital domain.
